(19) United States
(12) Patent Application Publication
(10) Pub. No.: US 2019/0067389 A1
(43) Pub. Date: Feb. 28, 2019

(54) OLED SUBSTRATE AND FABRICATION METHOD THEREOF

(71) Applicant: Shenzhen China Star Optoelectronics Semiconductor Display Technology Co., Ltd., Shenzhen City (CN)

(72) Inventors: Na Ai, Shenzhen City (CN); Rumei Lin, Shenzhen City (CN); Shinsuke Iguchi, Shenzhen City (CN)

(21) Appl. No.: 15/742,042

(22) PCT Filed: Nov. 17, 2017
(86) PCT No.: PCT/CN2017/111507

§ 371 Date: Jan. 5, 2018

(30) Foreign Application Priority Data
Aug. 30, 2017 (CN) 201710766538.7

(51) Int. Cl. H01L 27/32; H01L 51/00; H01L 51/56; H01L 51/52; H01L 51/50

(52) U.S. Cl. CPC H01L 27/3246; C23C 14/086; H01L 51/0005; H01L 51/001; H01L 51/56; H01L 51/5206; H01L 51/5221; H01L 51/5012; H01L 51/5088; H01L 51/5056; H01L 51/5072; H01L 2227/323; H01L 2251/308; H01L 2251/301; H01L 2251/558; H01L 51/0021

(57) ABSTRACT

The present invention provides an OLED substrate and a fabrication method thereof. The OLED substrate fabrication method of the present invention forms pixel areas of which shapes are each a first pattern that is made up of a rectangle and two semicircles that are respectively connected to two short edges of the rectangle or a second pattern that is made up of a rectangle having four corners that are each a round corner so as to improve homogeneity and consistency of film formation through inkjet printing in the pixel areas thereby enhancing lighting homogeneity and performance stability of an OLED device. The OLED substrate of the present invention is made to have uniform thickness for inkjet-printed films so as to achieve uniform lighting and stable performance of an OLED device.

### BACKGROUND OF THE INVENTION

### 1. Field of the Invention

The present invention relates to the field of display technology, and more particular to an OLED substrate and a fabrication method thereof.

### 2. The Related Arts

Organic light-emitting display (OLED) possesses various advantages, such as being self-luminous, low drive voltage, high luminous efficiency, short response time, high clarity and contrast, almost 180° view angle, wide range of operation temperature, and easy realization of flexible displaying and large-area full-color displaying, and is considered the most promising display device in the industry.

Based on the way of driving, OLEDs can be classified in two categories, passive matrix OLED (PMOLED) and active matrix OLED (AMOLED), namely two categories of direct addressing and TFT array addressing, among which the AMOLED comprises pixels that are arranged in an array and belongs to an active display type, having high light emission performance and being commonly used in high definition large-sized display devices.

An OLED is generally made up of a substrate, an anode arranged on the substrate, a hole injection layer arranged on and anode, a hole transport layer arranged on the hole injection layer, an emissive layer arranged on the hole transport layer, an electron transport layer arranged on the emissive layer, an electron injection layer arranged on the electron transport layer, and a cathode arranged on the electron injection layer. The principle of light emission of the OLED display device is that when a semiconductor material and an organic light emission material are driven by an electric field, carrier currents are injected and re-combine to cause emission of light. Specifically, the OLED display device often uses an indium tin oxide (ITO) electrode and a metal electrode to respectively serve as anode and cathode of the device and electrons and holes, when driven by a predetermined electrical voltage, are respectively injected into the electron transport layer and the hole transport layer from the cathode and the anode such that the electrons and the holes respectively migrate through the electron transport layer and the hole transport layer to get into the emissive layer and meet in the emissive layer to form excitons to excite light emissive molecules to emit light, the later undergoing radiation relaxation to give off visible light.

Techniques of color patternization through inject printing are now gradually accepted as a main-stream technology in the field of flat panel displays and the development and achievement of the technology attract great attention of the industry. The technology has been applied to the fabrication of OLED. A key issue of the technology is to realize a polymer film layer having a uniform thickness.

FIG. 1 is a schematic view showing a structure of conventional OLED substrate. As shown in FIG. 1, the conventional OLED substrate generally comprises a base plate (not shown), a pixel definition layer 100 arranged on the base plate, and an OLED device 300 arranged in a pixel area 200 surrounded by the pixel definition layer. The OLED device 300 comprises a plurality of structural layers, such as a hole injection layer, a hole transportation layer, and a light emission layer, which are all formed through inject printing operations. Heretofore, the pixel area 200 is generally made in a rectangular form and thus, the four corners of the rectangle often suffer deposition of a printing material, leading to an increased film thickness at the four corner and short edges of the rectangles, while the remaining portion has a film thickness that is smaller, thereby making the thickness of the film layer of the OLED device inconsistent in a single individual pixel area.

The OLED device is a typical dual-injection device, in which effective injection of carriers is the condition that a high-performance organic electroluminescent device can be provided. Generally, the metal cathode of an OLED has a work function that is lower, in energy level, than the lowest unoccupied molecular orbital (LUMO) of the material of the electron injection layer, while ITO of the anode has a work function having an energy level that is higher than that of the highest occupied molecular orbital (HOMO) of the material of the hole injection layer so that electrons and holes must cross certain barriers to get injected. Under the application of an external positive electric field, the energy band structure of the functional layers of the OLED device gets inclined, and the stronger the electric field is, the greater the inclination of the energy bands would be and the thinner the triangle of the barrier would be, providing a higher probability for the charge carriers to tunnel through the barrier. The electric field of the OLED device is generated by an electrical voltage applied to two terminals of the OLED device and under the same electrical voltage, the magnitude of the electric field is in inverse proportion to the film thickness. In other words, the energy level inclines less for a great film thickness and the probability that the charge carriers tunnel and inject in is reduced, leading to weak lighting or even no lighting at all. This reduces an effective light emission area of an OLED substrate and deteriorates performance stability of the OLED device.

### SUMMARY OF THE INVENTION

Objectives of the present invention are to provide an OLED substrate fabrication method, which effectively improves consistency and uniformity of film formation through inkjet printing in a pixel area so as to effectively enhance lighting homogeneity and performance stability of an OLED device.

Objectives of the present invention are also to provide an OLED substrate, in which a thickness of film formation through inkjet printing is consistent and uniform so as to achieve homogeneous lighting and stable performance of an OLED device.

To achieve the above objectives, the present invention provides an OLED substrate fabrication method, which comprises the following steps:

providing a backing plate and forming a plurality of anodes that are spaced from each other on the backing plate;

forming a pixel definition layer on the plurality of anodes and the backing plate, such that the pixel definition layer surrounds and delimits a plurality of pixel areas on the plurality of anodes, respectively, and the plurality of pixel areas each have a shape that comprises a first pattern or a second pattern, wherein the first pattern is made up of a rectangle and two semicircles respectively connected to two short edges of the rectangle and the second pattern is made up of a rectangle having four corners each comprising a rounded corner;

forming a plurality of hole injection layers in the plurality of pixel areas to be respectively located on the plurality of anodes;

forming a plurality of hole transportation layers on the plurality of hole injection layers, respectively;

forming a plurality of light emission layers on the plurality of hole transportation layers, respectively;

forming a plurality of electron transportation layers on the plurality of light emission layers, respectively; and

forming a plurality of cathodes on the plurality of electron transportation layers, respectively.

The first pattern, the semicircles have a radius that is one half of a length of the short edges of the rectangle; and in the second pattern, the round corners are each a quarter of a circle and the round corners have a radius that is one third or one fourth of a length of short edges of the rectangle.

The OLED substrate fabrication method further comprises: forming spacer pillars on the pixel definition layer, wherein the spacer pillars and the pixel definition layer are formed of the same material in the same process.

A magnetron sputtering based film formation operation is used to form the plurality of anodes; the plurality of anodes are formed of a material that comprises a transparent conductive metal oxide; and the anodes have a film thickness between 20 nm and 200 nm;

an inkjet printing based film formation operation is used to form the hole injection layers, and the hole injection layers have a film thickness between 60 nm and 100 nm; and

an inkjet printing based film formation operation is used to form the hole transportation layers, the hole transportation layers have a film thickness between 100 nm and 150 nm.

An inkjet printing based film formation operation is used to form the light emission layers, and the light emission layers have a film thickness between 60 nm and 100 nm;

a vapor deposition film formation operation is used to form the electron transportation layers, and the electron transportation layers have a film thickness between 0.5 nm and 20 nm; and

a vacuum vapor deposition film formation operation is used to form the cathodes; the cathodes are formed of a material that comprises aluminum; and the cathodes have a film thickness between 100 nm and 200 nm.

The present invention also provides an OLED substrate, which comprises:

a backing plate;

a plurality of anodes that are arranged on the backing plate and are spaced from each other;

a pixel definition layer that is arranged on the plurality of anodes and the backing plate, such that the pixel definition layer surrounds and delimits a plurality of pixel areas on the plurality of anodes, respectively, and the plurality of pixel areas each have a shape that comprises a first pattern or a second pattern, wherein the first pattern is made up of a rectangle and two semicircles respectively connected to two short edges of the rectangle and the second pattern is made up of a rectangle having four corners each comprising a rounded corner;

a plurality of hole injection layers that are respectively arranged in the plurality of pixel areas and are respectively located above the plurality of anodes;

a plurality of hole transportation layers that are respectively arranged on the plurality of hole injection layers;

a plurality of light emission layers that are respectively arranged on the plurality of hole transportation layers;

a plurality of electron transportation layers that are respectively arranged on the plurality of light emission layers; and

a plurality of cathodes that are respectively arranged on the plurality of electron transportation layers.

In the first pattern, the semicircles have a radius that is one half of a length of the short edges of the rectangle; and in the second pattern, the round corners are each a quarter of a circle and the round corners have a radius that is one third or one fourth of a length of short edges of the rectangle.

The OLED substrate further comprises: spacer pillars arranged on the pixel definition layer, wherein the spacer pillars and the pixel definition layer are formed of the same material in the same process.

The plurality of anodes are formed of a material that comprises a transparent conductive metal oxide and the anodes have a film thickness between 20 nm and 200 nm;

the hole injection layers have a film thickness between 60 nm and 100 nm; and

the hole transportation layers have a film thickness between 100 nm and 150 nm.

The light emission layers have a film thickness between 60 nm and 100 nm;

the electron transportation layers have a film thickness between 0.5 nm and 20 nm; and

the cathodes are formed of a material that comprises aluminum and the cathodes have a film thickness between 100 nm and 200 nm.

The present invention further provides an OLED substrate fabrication method, which comprises the following steps:

providing a backing plate and forming a plurality of anodes that are spaced from each other on the backing plate;

forming a pixel definition layer on the plurality of anodes and the backing plate, such that the pixel definition layer surrounds and delimits a plurality of pixel areas on the plurality of anodes, respectively, and the plurality of pixel areas each have a shape that comprises a first pattern or a second pattern, wherein the first pattern is made up of a rectangle and two semicircles respectively connected to two short edges of the rectangle and the second pattern is made up of a rectangle having four corners each comprising a rounded corner;

forming a plurality of hole injection layers in the plurality of pixel areas to be respectively located on the plurality of anodes;

forming a plurality of hole transportation layers on the plurality of hole injection layers, respectively;

forming a plurality of light emission layers on the plurality of hole transportation layers, respectively;

forming a plurality of electron transportation layers on the plurality of light emission layers, respectively; and

forming a plurality of cathodes on the plurality of electron transportation layers, respectively;

wherein in the first pattern, the semicircles have a radius that is one half of a length of the short edges of the rectangle; and in the second pattern, the round corners are each a quarter of a circle and the round corners have a radius that is one third or one fourth of a length of short edges of the rectangle;

further comprising: forming spacer pillars on the pixel definition layer, wherein the spacer pillars and the pixel definition layer are formed of the same material in the same process;

wherein a magnetron sputtering based film formation operation is used to form the plurality of anodes; the plurality of anodes are formed of a material that comprises a transparent conductive metal oxide; and the anodes have a film thickness between 20 nm and 200 nm;

an inkjet printing based film formation operation is used to form the hole injection layers, and the hole injection layers have a film thickness between 60 nm and 100 nm; and

an inkjet printing based film formation operation is used to form the hole transportation layers, the hole transportation layers have a film thickness between 100 nm and 150 nm; and

wherein an inkjet printing based film formation operation is used to form the light emission layers, and the light emission layers have a film thickness between 60 nm and 100 nm;

a vapor deposition film formation operation is used to form the electron transportation layers, and the electron transportation layers have a film thickness between 0.5 nm and 20 nm; and

a vacuum vapor deposition film formation operation is used to form the cathodes; the cathodes are formed of a material that comprises aluminum; and the cathodes have a film thickness between 100 nm and 200 nm.

The efficacy of the present invention is that the present invention provides an OLED substrate fabrication method, which forms pixel areas of which shapes are each a first pattern that is made up of a rectangle and two semicircles that are respectively connected to two short edges of the rectangle or a second pattern that is made up of a rectangle having four corners that are each a round corner so as to improve homogeneity and consistency of film formation through inkjet printing in the pixel areas thereby enhancing lighting homogeneity and performance stability of an OLED device. The present invention provides an OLED substrate that is made to have uniform thickness for inkjet-printed films so as to achieve uniform lighting and stable performance of an OLED device.

For better understanding of the features and technical contents of the present invention, reference will be made to the following detailed description of the present invention and the attached drawings. However, the drawings are provided only for reference and illustration and are not intended to limit the present invention.

### BRIEF DESCRIPTION OF THE DRAWINGS

The technical solution, as well as other beneficial advantages, of the present invention will become apparent from the following detailed description of embodiments of the present invention, with reference to the attached drawings.

In the drawings:

FIG. 1 is a schematic view showing a structure of a conventional OLED substrate;

FIG. 2 is a flow chart illustrating an OLED substrate fabrication method according to the present invention;

FIG. 3 is a schematic view illustrating Step S1 of the OLED substrate fabrication method according to the present invention;

FIG. 4 is a schematic view illustrating Step S2 of the OLED substrate fabrication method according to the present invention;

FIG. 5 is a schematic view illustrating two shapes available for a pixel area surrounded and delimited by a pixel definition layer formed in Step S2 of the OLED substrate fabrication method according to the present invention;

FIG. 6 is a schematic view illustrating Step S3 of the OLED substrate fabrication method according to the present invention;

FIG. 7 is a schematic view illustrating Step S4 of the OLED substrate fabrication method according to the present invention;

FIG. 8 is a schematic view illustrating Step S5 of the OLED substrate fabrication method according to the present invention;

FIG. 9 is a schematic view illustrating Step S6 of the OLED substrate fabrication method according to the present invention;

FIG. 10 is a schematic view illustrating Step S7 of the OLED packaging method according to the present invention and is also a schematic view illustrating a structure of an OLED substrate according to the present invention.

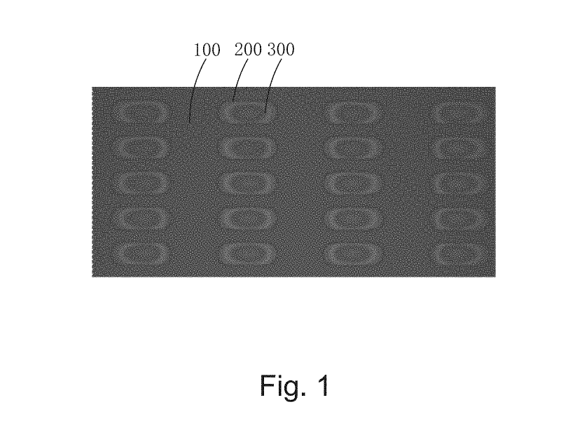

### DETAILED DESCRIPTION OF THE PREFERRED EMBODIMENTS

To further expound the technical solution adopted in the present invention and the advantages thereof, a detailed description will be given with reference to the preferred embodiments of the present invention and the drawings thereof.

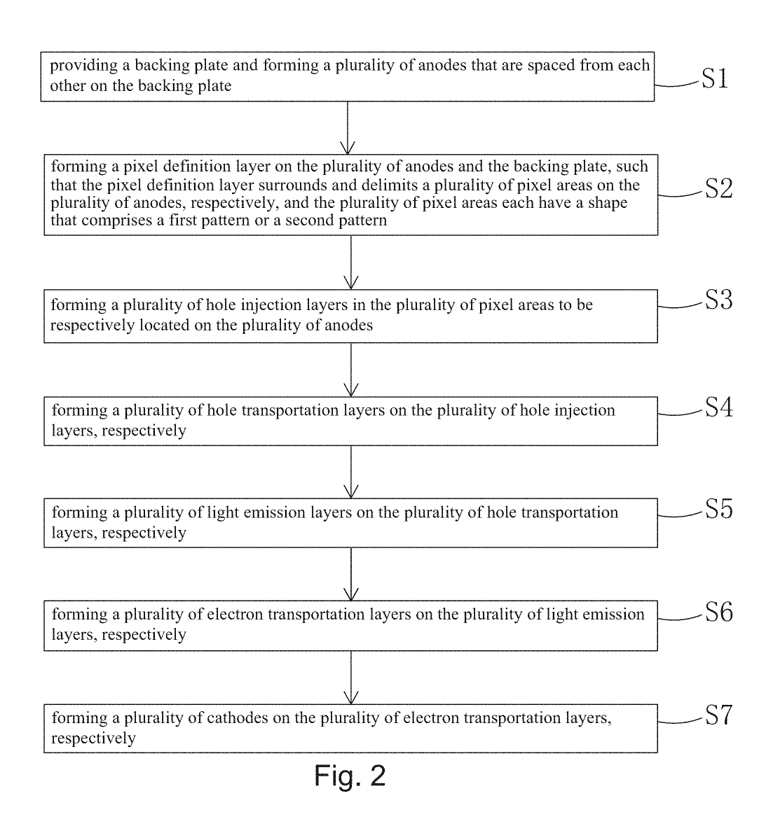

Referring to FIG. 2, the present invention provides an organic light emitting display (OLED) substrate fabrication method, which comprises the following steps:

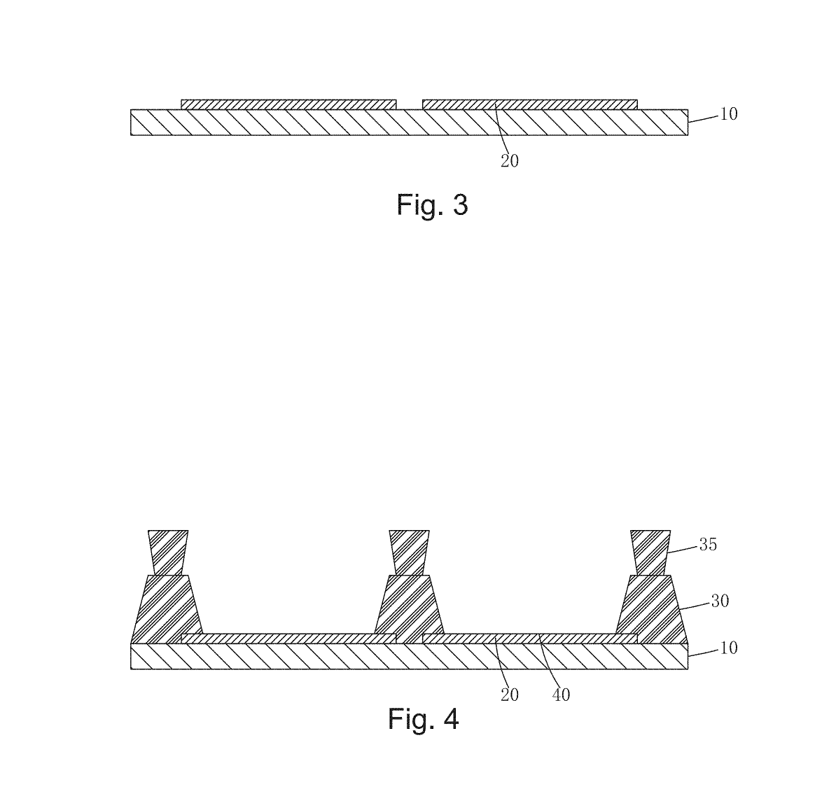

Step S1: as shown in FIG. 3, providing a backing plate 10 and forming a plurality of anodes 20 that are spaced from each other on the backing plate 10;

Specifically, the backing plate 10 comprises a transparent plate, preferably a glass plate.

Specifically, a magnetron sputtering based film formation operation is adopted to form the plurality of anodes 20. The plurality of anodes 20 are formed of a material that comprises a transparent conductive metal oxide. The anodes 20 have a film thickness between 20 nm and 200 nm. Preferably, the transparent conductive metal oxide is indium tin oxide (ITO).

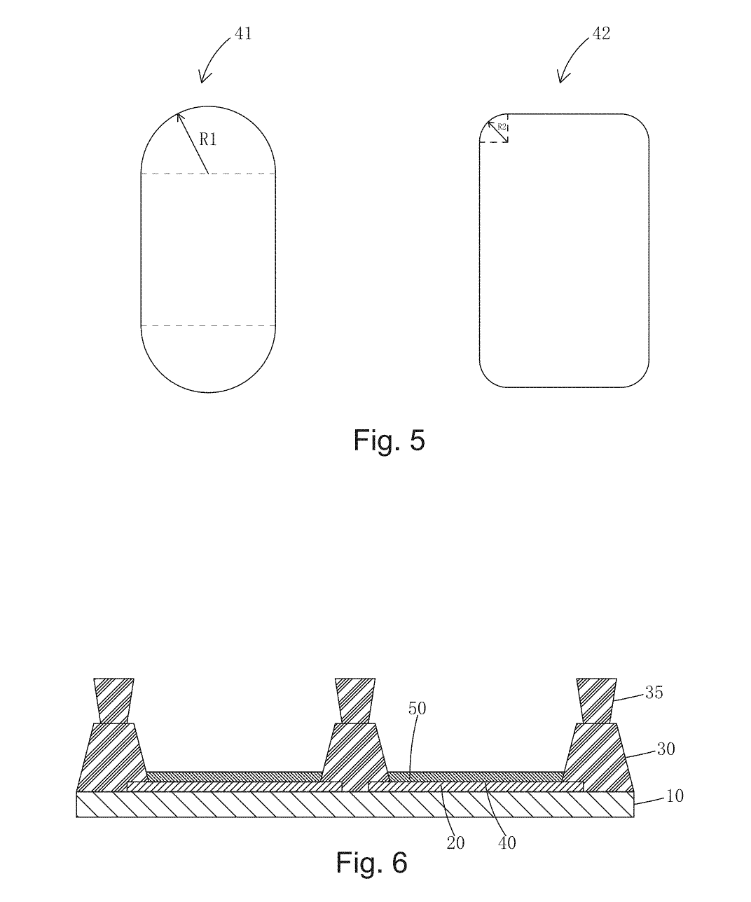

Step S2: as shown in FIGS. 4 and 5, forming a pixel definition layer 30 on the plurality of anodes 20 and the backing plate 10, such that the pixel definition layer 30 surrounds and delimits a plurality of pixel areas 40 on the plurality of anodes 20, respectively, and the plurality of pixel areas 40 each have a shape that comprises a first pattern 41 or a second pattern 42, wherein the first pattern 41 is made up of a rectangle and two semicircles respectively connected to two short edges of the rectangle and the second pattern 42 is made up of a rectangle having four corners each comprising a rounded corner.

Specifically, in the first pattern 41, the semicircles have a radius R1 that is one half of a length of the short edges of the rectangle; and in the second pattern 42, the round corners are each a quarter of a circle and the round corners have a radius R2 that is one third, or one fourth, or even smaller, of a length of short edges of the rectangle. By reducing the radius R2 of the round corner, the radius R2 of the round corner may be reduced from one third of the short edge to one fourth or even smaller so that a coverage area of the pixel area 40 can be increased to thereby increase an aperture ratio of a panel.

As shown in FIG. 5, the phantom lines shown in the first pattern 41 and the second pattern 42 do not actually exist and are provided for explaining the structural arrangements of the patterns.

By setting the shape of the pixel areas 40 to be one having round corners, compared to a rectangular pattern that was known and used, it is possible to prevent accumulation and deposition of a printing material at the four corners of the rectangle so as to enhance consistency and homogeneity of film formation through inkjet printing in the pixel areas 40 thereby guaranteeing a hole injection layer 50, a hole transportation layer 60, and a light emission layer 70 formed in a subsequent process through inkjet printing have uniform film thicknesses.

Specifically, the pixel definition layer 30 is formed of a material comprising an organic insulation material. Preferably, the pixel definition layer 30 is formed of a material comprising polyimide.

Preferably, Step S2 further comprises: forming spacer pillars 35 on the pixel definition layer 30, wherein the spacer pillars 35 and the pixel definition layer 30 are formed of the same material in the same process. The spacer pillars 35 are provided for supporting an encapsulation cover in a subsequent encapsulation process.

Step S3: as shown in FIG. 6, forming a plurality of hole injection layers 50 in the plurality of pixel areas 40 to be respectively located on the plurality of anodes 20.

Specifically, an inkjet printing based film formation operation is used to form the hole injection layers 50. The hole injection layers 50 have a film thickness between 60 nm and 100 nm. The hole injection layers 50 are formed of a material that is commonly used in this field of art and details will not be provided herein.

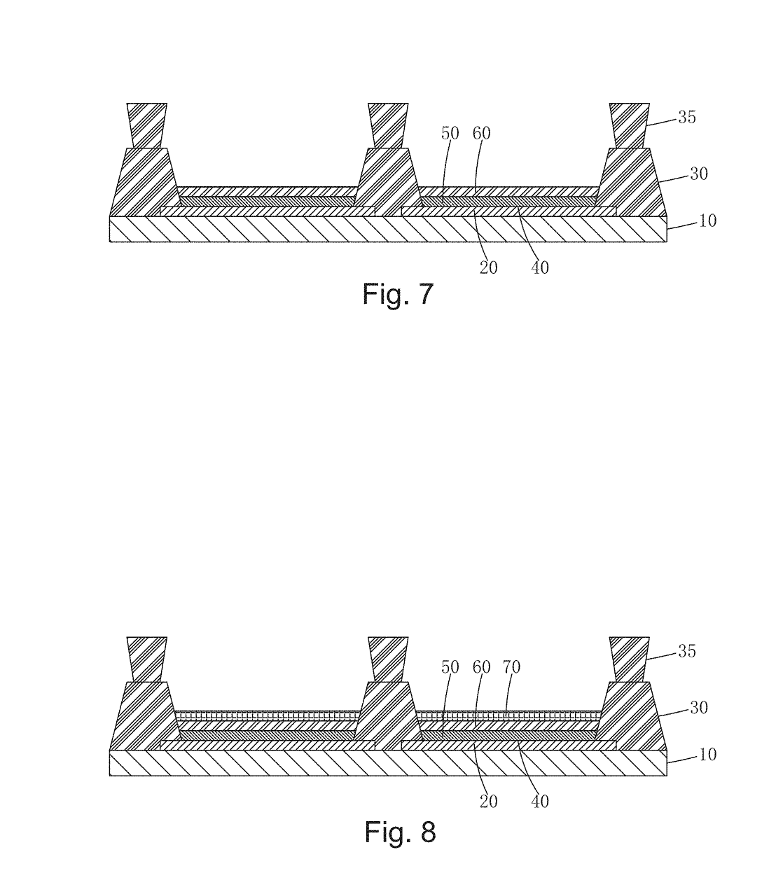

Step S4: as shown in FIG. 7, forming a plurality of hole transportation layers 60 on the plurality of hole injection layers 50, respectively.

Specifically, an inkjet printing based film formation operation is used to form the hole transportation layers 60. The hole transportation layers 60 have a film thickness between 100 nm and 150 nm. The hole transportation layers 60 are formed of a material that is commonly used in this field of art and details will not be provided herein.

Step S5: as shown in FIG. 8, forming a plurality of light emission layers 70 on the plurality of hole transportation layers 60, respectively.

Specifically, an inkjet printing based film formation operation is used to form the light emission layers 70. The light emission layers 70 have a film thickness between 60 nm and 100 nm. The light emission layers 70 are formed of a material that is commonly used in this field of art and details will not be provided herein.

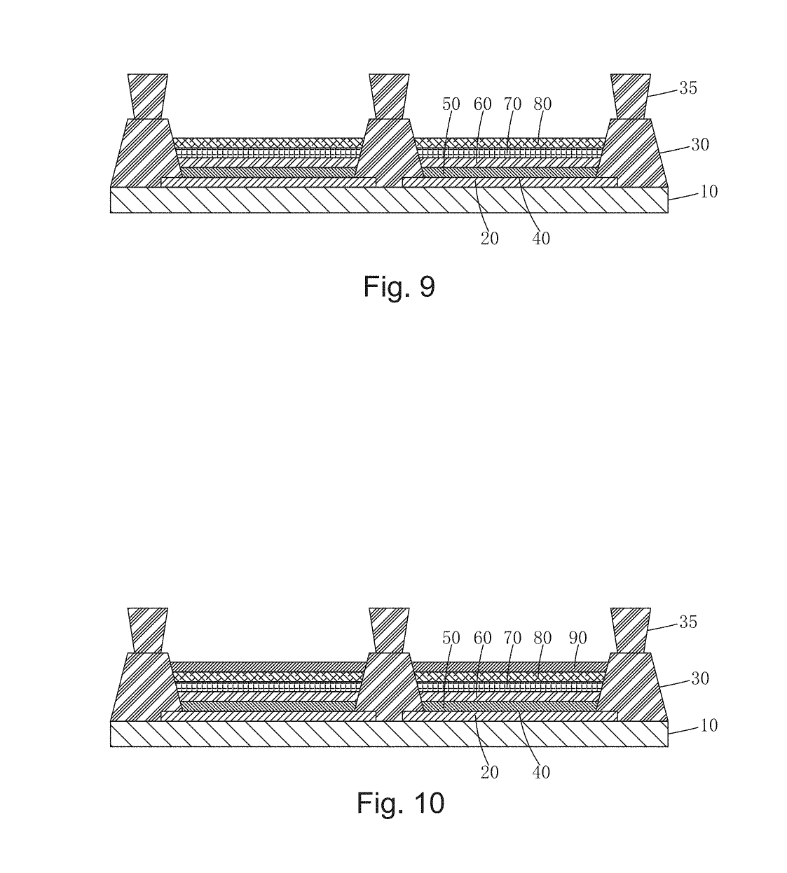

Step S6: as shown in FIG. 9, forming a plurality of electron transportation layers 80 on the plurality of light emission layers 70, respectively.

Specifically, a vapor deposition film formation operation is used to form the electron transportation layers 80. The electron transportation layers 80 have a film thickness between 0.5 nm and 20 nm. The electron transportation layers 80 are formed of a material that is commonly used in this field of art and details will not be provided herein.

Step S7: as shown in FIG. 10, forming a plurality of cathodes 90 on the plurality of electron transportation layers 80, respectively.

Specifically, a vacuum vapor deposition film formation operation is used to form the cathodes 90. The cathodes 90 are formed of a material that comprises aluminum. The cathodes 90 have a film thickness between 100 nm and 200 nm.

Specifically, in case that the pixel definition layer 30 is provided thereon with the spacer pillars 35, the cathode material can be applied through vapor deposition on the entire surface and no mask is necessary, wherein due to an effect of separation achieved with the spacer pillars 35, portions of the cathode material that fall into the plurality of pixel areas 40 respectively can be separated from each other to form the plurality of cathodes 90 that are separated from each other.

The present invention provides an OLED substrate fabrication method, which form pixel areas 40 of which shapes are each a first pattern 41 that is made up of a rectangle and two semicircles that are respectively connected to two short edges of the rectangle or a second pattern 42 that is made up of a rectangle having four corners that are each a round corner, both helping improving homogeneity and consistency of film formation through inkjet printing in the pixel areas 40 so as to enhance lighting homogeneity and performance stability of an OLED device.

Referring to FIG. 10, in combination with FIG. 5, based on the above-described OLED substrate fabrication method, the present invention provides an OLED substrate, which comprises:

a backing plate 10;

a plurality of anodes 20 that are arranged on the backing plate 10 and are spaced from each other;

a pixel definition layer 30 that is arranged on the plurality of anodes 20 and the backing plate 10, such that the pixel definition layer 30 surrounds and delimits a plurality of pixel areas 40 on the plurality of anodes 20, respectively, and the plurality of pixel areas 40 each have a shape that comprises a first pattern 41 or a second pattern 42, wherein the first pattern 41 is made up of a rectangle and two semicircles respectively connected to two short edges of the rectangle and the second pattern 42 is made up of a rectangle having four corners each comprising a rounded corner;

a plurality of hole injection layers 50 that are respectively arranged in the plurality of pixel areas 40 and are respectively located above the plurality of anodes 20;

a plurality of hole transportation layers 60 that are respectively arranged on the plurality of hole injection layers 50;

a plurality of light emission layers 70 that are respectively arranged on the plurality of hole transportation layers 60;

a plurality of electron transportation layers 80 that are respectively arranged on the plurality of light emission layers 70; and

a plurality of cathodes 90 that are respectively arranged on the plurality of electron transportation layers 80.

Specifically, the backing plate 10 comprises a transparent plate, preferably a glass plate.

Specifically, the plurality of anodes 20 are formed of a material that comprises a transparent conductive metal oxide. The anodes 20 have a film thickness between 20 nm and 200 nm. Preferably, the transparent conductive metal oxide is indium tin oxide (ITO).

Specifically, in the first pattern 41, the semicircles have a radius R1 that is one half of a length of the short edges of the rectangle; and in the second pattern 42, the round corners are each a quarter of a circle and the round corners have a radius R2 that is one third, or one fourth, or even smaller, of a length of short edges of the rectangle.

Specifically, the pixel definition layer 30 is formed of a material comprising an organic insulation material. Preferably, the pixel definition layer 30 is formed of a material comprising polyimide.

Preferably, the OLED substrate further comprises: spacer pillars 35 arranged on the pixel definition layer 30. The spacer pillars 35 and the pixel definition layer 30 are formed of the same material in the same process.

Specifically, the hole injection layers 50 have a film thickness between 60 nm and 100 nm. The hole injection layers 50 are formed of a material that is commonly used in this field of art and details will not be provided herein.

Specifically, the hole transportation layers 60 have a film thickness between 100 nm and 150 nm. The hole transportation layers 60 are formed of a material that is commonly used in this field of art and details will not be provided herein.

Specifically, the light emission layers 70 have a film thickness between 60 nm and 100 nm. The light emission layers 70 are formed of a material that is commonly used in this field of art and details will not be provided herein.

Specifically, the electron transportation layers 80 have a film thickness between 0.5 nm and 20 nm. The electron transportation layers 80 are formed of a material that is commonly used in this field of art and details will not be provided herein.

Specifically, the cathodes 90 are formed of a material that comprises aluminum. The cathodes 90 have a film thickness between 100 nm and 200 nm.

In the OLED substrate of the present invention, the hole injection layer 50, the hole transportation layer 60, and the light emission layer 70 are each formed through inkjet printing. The shapes of the pixel areas 40 are set to be one having round corners, so that it is possible to prevent accumulation and deposition of a printing material at the four corners of each of the pixel areas 40 so as to enhance consistency and homogeneity of film formation through inkjet printing in the pixel areas 40 thereby guaranteeing the hole injection layers 50, the hole transportation layers 60, and the light emission layers 70 have uniform film thicknesses.

The present invention provides an OLED substrate, which comprises pixel areas 40 of which shapes are each a first pattern 41 that is made up of a rectangle and two semicircles that are respectively connected to two short edges of the rectangle or a second pattern 42 that is made up of a rectangle having four corners that are each a round corner, so as to make thicknesses of films formed in the pixel areas 40 through inkjet printing consistent and uniform thereby providing an OLED device with uniform lighting and stable performance.

In summary, the present invention provides an OLED substrate and a fabrication method thereof. The OLED substrate fabrication method of the present invention forms pixel areas of which shapes are each a first pattern that is made up of a rectangle and two semicircles that are respectively connected to two short edges of the rectangle or a second pattern that is made up of a rectangle having four corners that are each a round corner so as to improve homogeneity and consistency of film formation through inkjet printing in the pixel areas thereby enhancing lighting homogeneity and performance stability of an OLED device. The OLED substrate of the present invention is made to have uniform thickness for inkjet-printed films so as to achieve uniform lighting and stable performance of an OLED device.

Based on the description given above, those having ordinary skills in the art may easily contemplate various changes and modifications of the technical solution and the technical ideas of the present invention. All these changes and modifications are considered belonging to the protection scope of the present invention as defined in the appended claims.

What is claimed is:

1. An organic light emitting display (OLED) substrate fabrication method, comprising the following steps:
providing a backing plate and forming a plurality of anodes that are spaced from each other on the backing plate;
forming a pixel definition layer on the plurality of anodes and the backing plate, such that the pixel definition layer surrounds and delimits a plurality of pixel areas on the plurality of anodes, respectively, and the plurality of pixel areas each have a shape that comprises a first pattern or a second pattern, wherein the first pattern is made up of a rectangle and two semicircles respectively connected to two short edges of the rectangle and the second pattern is made up of a rectangle having four corners each comprising a rounded corner;
forming a plurality of hole injection layers in the plurality of pixel areas to be respectively located on the plurality of anodes;
forming a plurality of hole transportation layers on the plurality of hole injection layers, respectively;
forming a plurality of light emission layers on the plurality of hole transportation layers, respectively;
forming a plurality of electron transportation layers on the plurality of light emission layers, respectively; and
forming a plurality of cathodes on the plurality of electron transportation layers, respectively.

2. The OLED substrate fabrication method as claimed in claim 1, wherein in the first pattern, the semicircles have a radius that is one half of a length of the short edges of the rectangle; and in the second pattern, the round corners are each a quarter of a circle and the round corners have a radius that is one third or one fourth of a length of short edges of the rectangle.

3. The OLED substrate fabrication method as claimed in claim 1 further comprising: forming spacer pillars on the pixel definition layer, wherein the spacer pillars and the pixel definition layer are formed of the same material in the same process.

4. The OLED substrate fabrication method as claimed in claim 1, wherein a magnetron sputtering based film formation operation is used to form the plurality of anodes; the plurality of anodes are formed of a material that comprises a transparent conductive metal oxide; and the anodes have a film thickness between 20 nm and 200 nm;
an inkjet printing based film formation operation is used to form the hole injection layers, and the hole injection layers have a film thickness between 60 nm and 100 nm; and
an inkjet printing based film formation operation is used to form the hole transportation layers, the hole transportation layers have a film thickness between 100 nm and 150 nm.

5. The OLED substrate fabrication method as claimed in claim 1, wherein an inkjet printing based film formation operation is used to form the light emission layers, and the light emission layers have a film thickness between 60 nm and 100 nm;
a vapor deposition film formation operation is used to form the electron transportation layers, and the electron transportation layers have a film thickness between 0.5 nm and 20 nm; and
a vacuum vapor deposition film formation operation is used to form the cathodes; the cathodes are formed of a material that comprises aluminum; and the cathodes have a film thickness between 100 nm and 200 nm.

6. An organic light emitting display (OLED) substrate, comprising:
a backing plate;
a plurality of anodes that are arranged on the backing plate and are spaced from each other;
a pixel definition layer that is arranged on the plurality of anodes and the backing plate, such that the pixel definition layer surrounds and delimits a plurality of pixel areas on the plurality of anodes, respectively, and the plurality of pixel areas each have a shape that comprises a first pattern or a second pattern, wherein the first pattern is made up of a rectangle and two semicircles respectively connected to two short edges of the rectangle and the second pattern is made up of a rectangle having four corners each comprising a rounded corner;
a plurality of hole injection layers that are respectively arranged in the plurality of pixel areas and are respectively located above the plurality of anodes;
a plurality of hole transportation layers that are respectively arranged on the plurality of hole injection layers;
a plurality of light emission layers that are respectively arranged on the plurality of hole transportation layers;
a plurality of electron transportation layers that are respectively arranged on the plurality of light emission layers; and
a plurality of cathodes that are respectively arranged on the plurality of electron transportation layers.

7. The OLED substrate as claimed in claim 6, wherein in the first pattern, the semicircles have a radius that is one half of a length of the short edges of the rectangle; and in the second pattern, the round corners are each a quarter of a circle and the round corners have a radius that is one third or one fourth of a length of short edges of the rectangle.

8. The OLED substrate as claimed in claim 6 further comprising: spacer pillars arranged on the pixel definition layer, wherein the spacer pillars and the pixel definition layer are formed of the same material in the same process.

9. The OLED substrate as claimed in claim 6, wherein the plurality of anodes are formed of a material that comprises a transparent conductive metal oxide and the anodes have a film thickness between 20 nm and 200 nm;
the hole injection layers have a film thickness between 60 nm and 100 nm; and
the hole transportation layers have a film thickness between 100 nm and 150 nm.

10. The OLED substrate as claimed in claim 6, wherein the light emission layers have a film thickness between 60 nm and 100 nm;
the electron transportation layers have a film thickness between 0.5 nm and 20 nm; and
the cathodes are formed of a material that comprises aluminum and the cathodes have a film thickness between 100 nm and 200 nm.

11. An organic light emitting display (OLED) substrate fabrication method, comprising the following steps:
providing a backing plate and forming a plurality of anodes that are spaced from each other on the backing plate;
forming a pixel definition layer on the plurality of anodes and the backing plate, such that the pixel definition layer surrounds and delimits a plurality of pixel areas on the plurality of anodes, respectively, and the plurality of pixel areas each have a shape that comprises a first pattern or a second pattern, wherein the first pattern is made up of a rectangle and two semicircles respectively connected to two short edges of the rectangle and the second pattern is made up of a rectangle having four corners each comprising a rounded corner;
forming a plurality of hole injection layers in the plurality of pixel areas to be respectively located on the plurality of anodes;
forming a plurality of hole transportation layers on the plurality of hole injection layers, respectively;
forming a plurality of light emission layers on the plurality of hole transportation layers, respectively;
forming a plurality of electron transportation layers on the plurality of light emission layers, respectively; and
forming a plurality of cathodes on the plurality of electron transportation layers, respectively;
wherein in the first pattern, the semicircles have a radius that is one half of a length of the short edges of the rectangle; and in the second pattern, the round corners are each a quarter of a circle and the round corners have a radius that is one third or one fourth of a length of short edges of the rectangle;
further comprising: forming spacer pillars on the pixel definition layer, wherein the spacer pillars and the pixel definition layer are formed of the same material in the same process;
wherein a magnetron sputtering based film formation operation is used to form the plurality of anodes; the plurality of anodes are formed of a material that comprises a transparent conductive metal oxide; and the anodes have a film thickness between 20 nm and 200 nm;
an inkjet printing based film formation operation is used to form the hole injection layers, and the hole injection layers have a film thickness between 60 nm and 100 nm; and
an inkjet printing based film formation operation is used to form the hole transportation layers, the hole transportation layers have a film thickness between 100 nm and 150 nm; and
wherein an inkjet printing based film formation operation is used to form the light emission layers, and the light emission layers have a film thickness between 60 nm and 100 nm;
a vapor deposition film formation operation is used to form the electron transportation layers, and the electron transportation layers have a film thickness between 0.5 nm and 20 nm; and
a vacuum vapor deposition film formation operation is used to form the cathodes; the cathodes are formed of a material that comprises aluminum; and the cathodes have a film thickness between 100 nm and 200 nm.
